(19) United States
(12) Patent Application Publication
(10) Pub. No.: US 2020/0031997 A1
(43) Pub. Date: Jan. 30, 2020

(54) TRANSPARENT POLYIMIDE FILMS AND METHOD OF PREPARATION

(71) Applicant: RayiTEK Hi-tech Film Company, Ltd., Shenzhen City (CN)

(72) Inventors: Xi REN, Shenzhen City (CN); Zhenzhong WANG, Shenzhen City (CN); Yong HU, Shenzhen City (CN); Wei ZHANG, Shenzhen City (CN)

(21) Appl. No.: 16/193,321

(22) Filed: Nov. 16, 2018

(30) Foreign Application Priority Data
Jul. 27, 2018 (CN) 201810841797.6

(51) Int. Cl. C08G 73/10; C08J 5/18; B29C 41/00; B29C 41/46; H01L 51/00

(52) U.S. Cl. CPC C08G 73/1067; C08G 73/1032; C08G 73/1021; C08J 5/18; G02F 1/133305; B29C 41/46; H01L 51/0035; C08J 2379/08; B29C 41/003

(57) ABSTRACT

A transparent polyimide film with low birefringence, high glass transition temperature (T_{g}) consists of polyimide essentially comprising non-linear structure. This polyimide is prepared by a mixture of dianhydrides and diamines, comprising at least 10 mol % of asymmetric dianhydride and 50 mol % or less of meta-substituted diamine. This transparent polyimide film has a transmittance of 85% or more at 550 nm, a birefringence value of 0.005 or less and a T_{g} of 300° C. or more. The present invention relates to the low birefringence required electro-optic field, including the substrate and cover window for flexible OLED and LCD displays.

### CROSS-REFERENCE TO RELATED APPLICATIONS

This application claims priority to Chinese application No. 201810841797.6, filed on 27 Jul. 2018, which is incorporated by reference as if fully recited herein.

### TECHNOLOGY FIELD

The current invention relates to a transparent polyimide film, particularly with low birefringence and high glass transition temperature (T_{g}), which can be applied to flexible display and other electro-optic fields, as well as the methods for preparing such films.

### BACKGROUND OF THE INVENTION

More recent trends of optical display industry are developing flexible and rollable liquid crystal display (LCD) and organic light emitting diodes (OLED). However, the most commonly utilized glass for display substrates and cover windows is thick, heavy, rigid, and friable, which cannot meet the new generation of flexible display requirements.

When compared to glass, polymeric materials show their inherent advantages over glass in flexibility, lightweight, and thinness, which make them a suitable substitute for glass in flexible display applications. Besides the flexibility, a good polymeric material that can replace glass should also have the following critical properties:

a. High transparency;

b. Colorless;

c. Low birefringence;

d. Good dimensional stability with relatively low coefficient of thermal expansion (CTE); and

e. Good thermal stability with high glass transition temperature (T_{g}) and low weight loss at high temperatures.

Many polymers can offer outstanding optical properties, but their poor thermal properties such as low T_{g} and high CTE limit their use in display applications. Polyimides, because of their excellent thermal stability and chemical resistance, are the most preferred polymeric material for this application. However, currently reported colorless polyimides have high birefringence values, which retards optical transmittance, reduces black and white contrast and increases color shift at wide viewing angles.

Birefringence arises from the anisotropic orientation of anisotropic material. This property affects the propagation of transmitted light. Polyimide film is typically an anisotropic material. The linear backbone chains of polyimide comprise lots of highly polarizable functional groups such as benzene and imide rings, which preferentially orient onto the plane of the substrate during the film making procedure. The anisotropic orientation of polyimide chain leads to different refractive index along the in-plane directions (parallel to the polyimide film plane) and out-of-plane direction (perpendicular to the polyimide film plane). Therefore, polyimide films show in-plane/out-of-plane birefringence (Δn ⊥), which is quantitatively determined by the difference between refractive index n(TE) and n(TM), according to the formula:

Δn⊥=n(TE)−n(TM),

wherein n(TE) is the refractive index in the direction parallel to the polyimide film plane, and n(TM) is the refractive index in the direction perpendicular to the polyimide film plane. The TE and TM are different refractive test modes and respectively represent transverse electric and transverse magnetic polarizations.

When present, birefringence always causes the optical retardation. Because of the difference between refractive indices, one ray will pass through the film at a slower rate than the other ray. In other words, the velocity of the slower ray will be retarded with respect to the faster ray. This retardation value along the thickness direction (Rth), perpendicular to the film plane, can be quantitatively calculated by the in-plane/out-of-plane birefringence (Δn⊥) and thickness (T), by the formula:

Rth=Δn⊥×T.

The magnitude of retardation will directly determine the display quality. The materials used for flexible OLED and LCD displays require low birefringence, which means that the refractive index along the direction parallel to film plane n(TE) and along the direction perpendicular to the film plane n(TM) must be equal or quite close.

As discussed above, the birefringence is an important value for polyimide film applied in display field. However, the reports about birefringence, particularly about the polyimide film with low birefringence and high T_{g} are less and infrequent.

U.S. Pat. No. 8,796,411 reports a polyimide prepared from 2,2′-trifluoromethylbenzidine, trans-1,4-cyclohexyl diamine, 3,3′,4,4′-bicyclohexyl tetracarboxylic dianhydride and 3,3′,4,4′-biphenyl tetracarboxylic dianhydride mixtures. A film produced from this polyimide has good transmittance of 83% at 400 nm and low CTE of 7 ppm/° C., but the reported birefringence is 0.04, which is too high to satisfy the requirement for optical display.

U.S. Pat. No. 7,550,194 has a report of a polyimide with low CTE, which is derived from 3,3′,4,4′-bicyclohexyl tetracarboxylic dianhydride, 4,4′-(4,4′-isopropylidenediphenoxy) bis(phthalic anhydride) and 2,2′-bis(trifluoromethyl)benzidine. This polyimide film has a T_{g} of 330° C. and a CTE of 9 ppm/° C., but it has an average transmittance of 76.07% in the range 380-770 nm, and it has been evaluated to have a larger birefringence that cannot exhibit good color reproducibility.

U.S. Pat. No. 9,221,954 discloses a colorless polyimide film comprising 4,4′-(hexafluoroisopropylidene) diphthalic anhydride, 4,4′-(4,4′-isopropylidenediphenoxy) bis(phthalic anhydride), 2,2-bis[4-(4-aminophenoxy)-phenyl] propane and 2,2′-bis(trifluoromethyl)benzidine. This colorless polyimide film has a transmittance of 88% or more at 550 nm, a birefringence of 0.01 or less, a yellow index of 5.0 or less. However, the polyimide film thus produced also has a low T_{g}, less than 300° C., and it is estimated to have poor chemical resistance to process solvents such as acetone and dimethyl acetamide. These deficiencies would cause problems during display manufacturing process.

U.S. Pat. No. 8,404,319 reports the preparation of a polyimide film with a low birefringence. However, by looking at the backbone of the chemical structure, this polyimide is anticipated to have a low transmittance and a low Tg, inadequate for cover window or substrate application requirement in flexible displays. What's more, this polyimide is soluble and has poor chemical resistance.

In the research about synthesizing polyimide with different structure and improving their properties, some researchers have already reported polyimides with asymmetric structure have some special physical properties. Changlu Gao (Macromolecules, 2004, 37:2754-2761), Jingang Liu (Journal of Aeronautical Materials, Vol. 27, No. 3 61-65) etc. have reported the polyimide prepared by using asymmetric dianhydride a-BPDA and diamine PDA, MDA, ODA, m-TEDAB, which have high transparency and improved solubility in chemical solvent. However, there are not related studies about the birefringence of polyimide film comprising asymmetric structure.

### SUMMARY

The present disclosure relates to a transparent polyimide film with a low birefringence and high T_{g}. Such a polyimide film is prepared from polyimide essentially comprising asymmetric dianhydride and meta-substituted diamine. This polyimide is prepared by polymerizing one or more dianhydride and diamine. The stereo chemical structure of such a compound suggests that the asymmetric dianhydride and the meta-substituted diamine can decrease the linear characteristics of the polyimide. The decreased linear characteristics can decrease the anisotropic orientation of the polyimide, thus reducing the birefringence of these polyimide films.

The polyimide according to the embodiment of the present invention is prepared from a mixture of dianhydrides and diamines. The dianhydrides used in this invention comprise asymmetric dianhydride in an amount of at 20-80 mol % and other dianhydrides in an amount of 80-20 mol % or less. The diamines used in this invention comprise meta-substituted diamine in an amount of 50 mol % or less and other diamines in an amount of at least of 50 mol %.

The asymmetric dianhydride used in the present invention may comprise one or more selected from 2,3,3′,4′-biphenyl dianhydride (“a-BPDA”), 4,4′-(hexafluoroisopropylidene) diphthalic anhydride (“a-6FDA”), 2,3,3′,4′-benzophenone dianhydride (“a-BTDA”), 2,2,3′,4′-diphenylsulfonetetracarboxylic dianhydride (“a-DSDA”), and 2,3,3′,4′-diphenyl ether tetracarboxylic acid dianhydride (“a-ODPA”). Of these, a preferred asymmetric dianhydride in the present invention is a-BPDA.

The meta-substituted diamine used in the present invention is one or more selected from 1,3-benzenediamine (“m-PDA”), 3,3′-diaminodiphenylsulfone (“3,3′-DDS”), 1,3-cyclohexanediamine (“1,3-CHDA”), 1,3-cyclohexanebis(methylamine) (“CBMA”), 3,4′-oxydianiline (“3,4′-ODA”), 3-(3-aminophenoxy)aniline (“3,3-ODA”), 3-aminobenzylamine, 3,3′-diaminodiphenylmethane, 2,7-diaminofluorene, 1,3-bis(aminomethyl)benzene (“MXDA”), 1,3-bis (3-aminophenoxy)benzene (“1,3,3-APB”), 2,2-Bis(3-amino-4-hydroxyphenyl)hexafluoropropane (“DBOH”), 2,2-bis(3-aminophenyl)hexafluoropropane (“3,3′-6F”), 1,4-bis (3-aminophenoxy)benzene (“1,4,3-APB”), 2,2-bis(3-amino-4-methylphenyl)hexafluoropropane, bis[4-(3-aminophenoxy)-phenyl] sulfone, 3,3′-diaminobenzophenone, 3,4′-diaminodiphenyl ether, 3,3′-trifluoromethylbenzidine (“3,3′-TFMB”), 5-trifluoromethyl-1,3-benzenediamine, and 1,2-bis(3-aminophenoxy) benzene (“1,2,3-BAPB”). Of these, the preferred meta-substituted diamine in the present invention is 1,3-benzenediamine.

In the present invention, the other dianhydride may be one or more chosen from 3,3′,4,4′-benzophenonetetracarboxylic dianhydride (“BTDA”), 3,3′,4,4′-biphenyl tetracarboxylic dianhydride (“BPDA”), 4,4′-(hexafluoroisopropylidene)diphthalic anhydride (“6FDA”), 3,3′,4,4′-diphenylsulfonetetracarboxylic dianhydride (“DSDA”), bicyclo[2,2,2]otc-7-ene-2,3,5,6-tetracarboxylic dianhydride (“BTA”), bis-(3-phthalyl anhydride) ether (“ODPA”), 4,4′-(4,4′-isopropylidenediphenoxy)bis(phthalic anhydride) (“HBDA”), 4-(2,5-Dioxotetrahydrofuran-3-yl)-1,2,3,4-tetrahydronaphthalene-1,2-dicarboxylic anhydride (“TDA”), 1,2,4,5-cyclohexanetetracarboxylic dianhydride (“HPMDA”), cyclobutane-1,2,3,4-tetracarboxylic acid dianhydride (“CBDA”), and 1,2,3,4-cyclopentanetetracarboxylic dianhydride (“CPDA”).

In the present invention, the other diamines may be one or more chosen from 2,2′-trifluoromethylbenzidine (“TFMB”), 4,4′-[1,4-phenylenebis(oxy)] bis[3-(trifluoromethyl]benzenamine (“6FAPB”), 2,2′-bis-trifluoromethoxy-biphenyl-4,4′-diamine (“BTMBD”), 2,2-bis[4-(4-aminophenoxy)phenyl]hexafluoropropane (“HFBAPP”), 2,2-bis(4-aminophenyl)hexafluoropropane, 9,9-bis(4-amino-3-fluorophenyl)fluorene (“FFDA”), 1,4-cyclohexylenediamine (“1,4-CHDA”), 1,4-cyclohexanedimethanamine (“1,4-CHDMA”), 1,1-bis(4-aminophenyl)-cyclohexane, and 4,4′-diaminooctafluorobiphenyl. The preferred diamine in the present invention is TFMB.

In a preferred embodiment, the dianhydrides comprise 2,3,3′,4′-biphenyl dianhydride and other dianhydrides. The other dianhydride is BPDA or 6FDA, wherein BPDA account for 40-80 mol % of the total dianhydride.

In an embodiment, the diamines comprise m-PDA and TFMB, wherein m-PDA accounts for 20-50 mol % of total diamine. In another embodiment, the diamine is TFMB.

The more preferred embodiment discloses the amount of 2,3,3′,4′-biphenyl dianhydride is selected from 20 mol %, 40 mol %, 60 mol % or 80 mol %. The diamines comprise 1,3-benzenediamine and TFMB, wherein the amount of 1,3-benzenediamine is selected from 0 mol %, 20 mol %, 40 mol % or 50 mol %.

Another object of the invention is to disclose a method of making such polyimide film. A polyamic acid solution is prepared by polymerizing dianhydrides and diamines in solvent, wherein the solvent comprises one or more selected from N-methyl-2-pyrrolidone (“NMP”), dimethylacetamide (“DMAc”), dimethylformamide (“DMF”), dimethylsulfoxide (“DMSO”), m-cresol, chloroform, terahydrofuran (“THF”), y-butyrolactone, and 3-methoxy-N, N-dimethylpropanamide. The molar ratio, which will affect the final molecular weight and properties, is selected from 0.98-1.05.

Then, using a thermal imidization method, chemical imidization method or the combined method, the imidization is completed of obtained polyamic acid solution to get film. The thermal imidization method is carried out by casting film on a glass plate and curing in a high temperature oven, while the chemical imidization method is carried out by adding catalyst and dehydrant into polymer and then casting the obtained polyamic acid solution on glass, followed by curing in an oven.

The catalyst applied in the embodiment of the present invention can be one or more selected from pyridine, methyl pyridines, quinoline, isoquinoline, 1-methyl imidazole, 1, 2-dimethyl imidazole and 2-methyl imidazole.

The dehydrating agent applied in the embodiment of the present invention can be one or more selected from acetic anhydride, propionic anhydride, butyric anhydride, benzoic anhydride and other aliphatic or aromatic acid anhydride.

The chemical imidization method can provide polyimide film with better optical, thermal and mechanical properties. What's more, the polyimide film prepared by chemical method has a higher degree of orientation, which is believed to be because the imidization reaction can start at a relative low temperature. At this time, a much higher solvent content will facilitate the polymer chain to orientate. Therefore, the birefringence of polyimide film made by chemical method is larger than the thermal method.

By heating polyamic acid film at 60° C.˜100° C. for 30-60 minutes, most of the solvent is removed, using a heating plate or an oven, followed by curing the film at 80° C.˜400° C. for 30-120 minutes.

The polyamic acid solution of the present invention may be cast or applied onto a glass plate, a steel plate or a copper plate. The ring closure reaction of polyimide film in the present invention is performed on the glass plate, or on a steel pin frame. The film fixed by a steel pin frame conducts the imide conversion in an oven under the stress of shrinkage from the direction along the film plane. In contrast, the film cast on glass carries out the imide conversion procedure under the stress in a random direction perpendicular to the film plane. The stress from random direction perpendicular to the substrate constraints the orientation of the polymer chain in the direction perpendicular to the substrate. Therefore, the polyimide film cured on the glass or other support substrates has a larger birefringence than the film cured on a steel pin frame.

A shrinkage always occurs in the film with the evaporation of solvent during the curing process, so the obtained polyimide film always has internal stress. In order to reduce the negative impact of stress, the polyimide film is subsequently subjected to reheating treatment at 200˜400° C. for 2˜60 mins after the cure process.

The polyimide is vulnerable to small oxidation in the high temperature imidization process, which may impart a little yellowish tint to the film. To suppress the discoloration, nitrogen, argon or other inert gas may be used replacing air. High purity nitrogen gas is applied to create a near oxygen free atmosphere in the embodiment of the present invention.

The polyimide film in this invention may include one or more additives. Such additives comprise reaction aids, antioxidant, heat stabilizers, anti-tearing additives, glass fiber, graphene, carbon tube, inorganic fillers, different reinforcing agents and other optical additives.

In embodiments of the present invention, the polyimide film has a thickness from 5˜300 μm, preferably film thicknesses are selected from 20˜200 μm suitable for display applications.

The polyimide in the present invention have the following characteristics: the transmittance at 550 nm is 85% or more, the birefringence is 0.005 or less, the Tg is 300° C. or more. The polyimide film with aforementioned properties can be used in the low birefringence required field, particularly electronic devices, still particularly in fabricating flexible OLED and LCD displays.

### DETAILED DESCRIPTION OF THE EMBODIMENTS

Examples of the inventive concept are presented as described below. Nevertheless, the examples are only for elaborating the inventive concept and are not intended to limit the present invention thereto.

### Example 1

A 500 ml three neck round bottom flask fitted with a nitrogen inlet and mechanical stir was added 245.60 g of solvent N, N-dimethylacetamide followed by 32.00 g (0.1 mol) of 2,2′-trifluoromethylbenzidine (TFMB). The mixture was stirred at 50° C. to dissolve the diamines to get a clear solution. Then, 23.52 g (0.08 mol) 3,3′,4,4′-biphenyl tetracarboxylic dianhydride (BPDA) and 5.88 g (0.02 mol) 2,3,3′,4′-biphenyl tetracarboxylic dianhydride (a-BPDA) were added slowly to react with diamine. The mixture was then stirred at ice water bath for 15 hours, to get a polyamic acid solution with a viscosity of 1200 poise.

The polyamic acid solution obtained above was cast on a glass plate and imidized by thermal method to provide a 50 μm cured film. The glass plate with the wet polyamic acid film was heated at 100° C. for 15 mins to remove part of the solvent, and the semi-dried film was removed from the plate and restrained onto a steel pin frame. The film was then thermally imidized in the forced nitrogen oven at the following temperature, 150° C. for 30 mins, 250° C. for 30 mins, 300° C. for 30 mins, 350° C. for 20 mins. The film was removed from the steel frame and analyzed.

100.00 g of polyamic acid solution obtained above was stirred with 1.28 g pyridine and 1.65 g acetic anhydride. Then the solution mixture was cast on a glass plate and imidized in an oven to remove part of the solvent. The semi-dried film was peeled off from the plate and constrained in a pin frame and heated in the forced nitrogen oven at following temperatures, 150° C. for 30 mins, 250° C. for 30 mins, 300° C. for 20 mins. The film was removed from the steel frame and analyzed.

The refractive indices along the principal directions, n(TE) and n(TM) were measured by Metricon Prism Coupler 2010 at 637.3 nm by detecting the appropriate polarization of the incident laser beam and by rotating the sample direction. The difference between the refractive index in TE and TM mode was regarded as in-plane/out-of-plane birefringence (Δn⊥), which is calculated as Δn⊥=n(TE)−n(TM).

Transmittance, b*, yellow index and haze values were measured by x-rite UV-Vis Ci7800 spectrophotometric detector.

The glass transition temperature was measured by a TA Q20 instrument from 50° C.-400° C., at a ramp rate of 3 K/min. To remove the heat history, the second scan was done up to the T_{g} of polyimide film.

### Example 2

A 500 ml three neck round bottom flask fitted with a nitrogen inlet and mechanical stir was added to 245.60 g of solvent N, N-dimethylacetamide followed by 32.00 g (0.1 mol) of 2,2′-trifluoromethylbenzidine (TFMB). The mixture was stirred at 50° C. to dissolve the diamines to get a clear solution. Then, 17.64 g (0.06 mol) 3,3′,4,4′-biphenyl tetracarboxylic dianhydride (BPDA) and 11.76 g (0.04 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 800 poise.

The polyamic acid solution obtained above was cast and imidized by thermal method and chemical method to make 50 um polyimide film. 1.27 g pyridine and 1.63 g acetic anhydride was added into the polyamic acid solution as a chemical conversion agent, the film casting and imidization procedure is the same as Example 1 describes. The obtained polyimide film was used to do a related test.

### Example 3

A 500 ml three neck round bottom flask fitted with a nitrogen inlet and mechanical stirrer was added to 245.60 g of solvent N, N-dimethylacetamide followed by 32.00 g (0.1 mol) of 2,2′-trifluoromethylbenzidine (TFMB). The mixture was stirred at 50° C. to dissolve the diamines to get a clear solution. Then, 11.76 g (0.04 mol) 3,3′,4,4′-biphenyl tetracarboxylic dianhydride (BPDA) and 17.64 g (0.06 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 300 poise.

The polyamic acid solution obtained above was cast and imidized by thermal method and chemical method to make 50 um polyimide film. 1.25 g pyridine and 1.62 g acetic anhydride was added into the polyamic acid solution as a chemical conversion agent, the film casting and imidization procedure is the same as Example 1 describes. The obtained polyimide film was used to do a related test.

### Example 4

A 500 ml three neck round bottom flask fitted with a nitrogen inlet and mechanical stirrer was added to 245.60 g of solvent N, N-dimethylacetamide followed by 32.00 g (0.1 mol) of 2,2′-trifluoromethylbenzidine (TFMB). The mixture was stirred at 50° C. to dissolve the diamines to get a clear solution. Then, 5.88 g (0.02 mol) 3,3′,4,4′-biphenyl tetracarboxylic dianhydride (BPDA) and 23.52 g (0.08 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 100 poise.

The polyamic acid solution obtained above was cast and imidized by thermal method and chemical method to make 50 um polyimide film. 1.24 g pyridine and 1.61 g acetic anhydride was added into the polyamic acid solution as a chemical conversion agent, the film casting and imidization procedure is the same as Example 1 describes. The obtained polyimide film was used to do a related test.

### Example 5

A 500 ml three neck round bottom flask fitted with a nitrogen inlet and mechanical stirrer was added to 293.60 g of solvent N, N-dimethylacetamide followed by 32.00 g (0.1 mol) of 2,2′-trifluoromethylbenzidine (TFMB). The mixture was stirred at 50° C. to dissolve the diamines to get a clear solution. Then, 35.52 g (0.08 mol) 4,4′-(hexafluoroisopropylidene)diphthalic anhydride (6FDA) and 5.88 g (0.02 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 1700 poise.

The polyamic acid solution obtained above was cast and imidized by thermal method and chemical method to make 50 um polyimide film. 1.07 g pyridine and 1.38 g acetic anhydride was added into the polyamic acid solution as a chemical conversion agent, the film casting and imidization procedure is the same as Example 1 describes. The obtained polyimide film was used to do a related test.

### Example 6

A 500 ml three neck round bottom flask fitted with a nitrogen inlet and mechanical stirrer was added to 281.60 g of solvent N,N-dimethylacetamide followed by 32.00 g (0.1 mol) of 2,2′-trifluoromethylbenzidine (TFMB). The mixture was stirred at 50° C. to dissolve the diamines to get a clear solution. Then, 26.64 g (0.06 mol) 4,4′-(hexafluoroisopropylidene) diphthalic anhydride (6FDA) and 11.76 g (0.04 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 900 poise.

The polyamic acid solution obtained above was cast and imidized by thermal method and chemical method to make 50 um polyimide film. 1.11 g pyridine and 1.43 g acetic anhydride was added into the polyamic acid solution as a chemical conversion agent, the film casting and imidization procedure is the same as Example 1 describes. The obtained polyimide film was used to do a related test.

### Example 7

A 500 ml three neck round bottom flask fitted with a nitrogen inlet and mechanical stirrer was added to 269.60 g of solvent N,N-dimethylacetamide followed by 32.00 g (0.1 mol) of 2,2′-trifluoromethylbenzidine (TFMB). The mixture was stirred at 50° C. to dissolve the diamines to get a clear solution. Then, 17.76 g (0.04 mol) 4,4′-(hexafluoroisopropylidene) diphthalic anhydride (6FDA) and 17.64 g (0.06 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 400 poise.

The polyamic acid solution obtained above was cast and imidized by thermal method and chemical method to make 50 um polyimide film. 1.15 g pyridine and 1.37 g acetic anhydride was added into the polyamic acid solution as a chemical conversion agent, the film casting and imidization procedure is the same as Example 1 describes. The obtained polyimide film was used to do a related test.

### Example 8

A 500 ml three neck round bottom flask fitted with a nitrogen inlet and mechanical stirrer was added to 257.60 g of solvent N,N-dimethylacetamide followed by 32.00 g (0.1 mol) of 2,2′-trifluoromethylbenzidine (TFMB). The mixture was stirred at 50° C. to dissolve the diamines to get a clear solution. Then, 8.88 g (0.02 mol) 4,4′-(hexafluoroisopropylidene)diphthalic anhydride (6FDA) and 23.52 g (0.08 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 100 poise.

The polyamic acid solution obtained above was cast and imidized by thermal method and chemical method to make 50 um polyimide film. 1.19 g pyridine and 1.53 g acetic anhydride was added into the polyamic acid solution as a chemical conversion agent, the film casting and imidization procedure is the same as Example 1 describes. The obtained polyimide film was used to do a related test.

### Example 9

A 500 ml three neck round bottom flask fitted with a nitrogen inlet and mechanical stirrer was added to 228.64 g of solvent N,N-dimethylacetamide followed by 25.60 g (0.08 mol) of 2,2′-trifluoromethylbenzidine (TFMB) and 2.16 g (0.02 mol) of 1,3-benzenediamine (m-PDA). The mixture was stirred at 50° C. to dissolve the diamines to get a clear solution. Then, 23.52 g (0.08 mol) 3,3′,4,4′-biphenyl tetracarboxylic dianhydride (BPDA) and 5.88 g (0.02 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 1700 poise.

The polyamic acid solution obtained above was cast and imidized by thermal method and chemical method to make 50 um polyimide film. 1.37 g pyridine and 1.77 g acetic anhydride was added into the polyamic acid solution as a chemical conversion agent, the film casting and imidization procedure is the same as Example 1 describes. The obtained polyimide film was used to do a related test.

### Example 10

A 500 ml three neck round bottom flask fitted with a nitrogen inlet and mechanical stirrer was added to 211.68 g of solvent N, N-dimethylacetamide followed by 19.20 g (0.06 mol) of 2,2′-trifluoromethylbenzidine (TFMB) and 4.32 g (0.04 mol) of 1,3-benzenediamine (m-PDA). The mixture was stirred at 50° C. to dissolve the diamines to get a clear solution. Then, 17.64 g (0.06 mol) 3,3′,4,4′-biphenyl tetracarboxylic dianhydride (BPDA) and 11.76 g (0.04 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 1600 poise.

The polyamic acid solution obtained above was cast and imidized by thermal method and chemical method to make 50 um polyimide film. 1.46 g pyridine and 1.89 g acetic anhydride was added into the polyamic acid solution as a chemical conversion agent, the film casting and imidization procedure is the same as Example 1 describes. The obtained polyimide film was used to do a related test.

### Example 11

A 500 ml three neck round bottom flask fitted with a nitrogen inlet and mechanical stir was added to 203.20 g of solvent N, N-dimethylacetamide followed by 16.00 g (0.05 mol) of 2,2′-trifluoromethylbenzidine (TFMB) and 5.40 g (0.05 mol) of 1,3-benzenediamine (m-PDA). The mixture was stirred at 50° C. to dissolve the diamines to get a clear solution. Then, 17.64 g (0.06 mol) 3,3′,4,4′-biphenyl tetracarboxylic dianhydride (BPDA) and 11.76 g (0.04 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 700 poise.

The polyamic acid solution obtained above was cast and imidized by thermal method and chemical method to make 50 um polyimide film. 1.51 g pyridine and 1.95 g acetic anhydride was added into the polyamic acid solution as a chemical conversion agent, the film casting and imidization procedure is the same as Example 1 describes. The obtained polyimide film was used to do a related test.

### Example 12

A 500 ml three neck round bottom flask fitted with a nitrogen inlet and mechanical stir was added to 203.20 g of solvent N, N-dimethylacetamide followed by 16.00 g (0.05 mol) of 2,2′-trifluoromethylbenzidine (TFMB) and 5.40 g (0.05 mol) of 1,3-benzenediamine (m-PDA). The mixture was stirred at 50° C. to dissolve the diamines to get a clear solution. Then, 5.88 g (0.02 mol) 3,3′,4,4′-biphenyl tetracarboxylic dianhydride (BPDA) and 23.52 g (0.08 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 300 poise.

The polyamic acid solution obtained above was cast and imidized by thermal method and chemical method to make 50 um polyimide film. 1.49 g pyridine and 1.93 g acetic anhydride was added into the polyamic acid solution as a chemical conversion agent, the film casting and imidization procedure is the same as Example 1 describes. The obtained polyimide film was used to do a related test.

### Example 13

A 500 ml three neck round bottom flask fitted with a nitrogen inlet and mechanical stirrer was added to 276.64 g of solvent N, N-dimethylacetamide followed by 25.60 g (0.08 mol) of 2,2′-trifluoromethylbenzidine (TFMB) and 2.16 g (0.02 mol) of 1,3-benzenediamine (m-PDA). The mixture was stirred at 50° C. to dissolve the diamines to get a clear solution. Then, 35.52 g (0.08 mol) 4,4′-(hexafluoroisopropylidene)diphthalic anhydride (6FDA) and 5.88 g (0.02 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 1900 poise.

The polyamic acid solution obtained above was cast and imidized by thermal method and chemical method to make 50 um polyimide film. 1.13 g pyridine and 1.49 g acetic anhydride was added into the polyamic acid solution as a chemical conversion agent, the film casting and imidization procedure is the same as Example 1 describes. The obtained polyimide film was used to do a related test.

### Example 14

A 500 ml three neck round bottom flask fitted with a nitrogen inlet and mechanical stirrer was added to 247.68 g of solvent N, N-dimethylacetamide followed by 19.20 g (0.06 mol) of 2,2′-trifluoromethylbenzidine (TFMB) and 4.32 g (0.04 mol) of 1,3-benzenediamine (m-PDA). The mixture was stirred at 50° C. to dissolve the diamines to get a clear solution. Then, 26.64 g (0.06 mol) 4,4′-(hexafluoroisopropylidene)diphthalic anhydride (6FDA) and 11.76 g (0.04 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 1300 poise.

The polyamic acid solution obtained above was cast and imidized by thermal method and chemical method to make 50 um polyimide film. 1.25 g pyridine and 1.62 g acetic anhydride was added into the polyamic acid solution as a chemical conversion agent, the film casting and imidization procedure is the same as Example 1 describes. The obtained polyimide film was used to do a related test.

### Example 15

A 500 ml three neck round bottom flask fitted with a nitrogen inlet and mechanical stirrer was added to 227.20 g of solvent N, N-dimethylacetamide followed by 16.00 g (0.05 mol) of 2,2′-trifluoromethylbenzidine (TFMB) and 5.40 g (0.05 mol) of 1,3-benzenediamine (m-PDA). The mixture was stirred at 50° C. to dissolve the diamines to get a clear solution. Then, 17.76 g (0.04 mol) 4,4′-(hexafluoroisopropylidene)diphthalic anhydride (6FDA) and 17.64 g (0.06 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 600 poise.

The polyamic acid solution obtained above was cast and imidized by thermal method and chemical method to make 50 um polyimide film. 1.25 g pyridine and 1.62 g acetic anhydride was added into the polyamic acid solution as a chemical conversion agent, the film casting and imidization procedure is the same as Example 1 describes. The obtained polyimide film was used to do a related test.

### Example 16

A 500 ml three neck round bottom flask fitted with a nitrogen inlet and mechanical stirrer was added to 215.20 g of solvent N, N-dimethylacetamide followed by 16.00 g (0.05 mol) of 2,2′-trifluoromethylbenzidine (TFMB) and 5.40 g (0.05 mol) of 1,3-benzenediamine (m-PDA). The mixture was stirred at 50° C. to dissolve the diamines to get a clear solution. Then, 8.88 g (0.02 mol) 4,4′-(hexafluoroisopropylidene)diphthalic anhydride (6FDA) and 23.52 g (0.08 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 200 poise.

The polyamic acid solution obtained above was cast and imidized by thermal method and chemical method to make 50 um polyimide film. 1.41 g pyridine and 1.83 g acetic anhydride was added into the polyamic acid solution as a chemical conversion agent, the film casting and imidization procedure is the same as Example 1 describes. The obtained polyimide film was used to do a related test.

### Comparative Example 1

A 500 ml three neck round bottom flask fitted with a nitrogen inlet and mechanical stirrer was added to 245.60 g of solvent N, N-dimethylacetamide followed by 32.00 g (0.1 mol) of 2,2′-trifluoromethylbenzidine (TFMB). The mixture was stirred at 50° C. to dissolve the diamines to get a clear solution. Then, 29.40 g (0.1 mol) 3,3′,4,4′-biphenyl tetracarboxylic dianhydride (BPDA) was added slowly to react with diamine. The mixture was then stirred at an ice water bath for 15 hours, to get a polyamic acid solution with a viscosity of 1540 poise.

The polyamic acid solution obtained above was cast and imidized by thermal method and chemical method to make 50 um polyimide film. 1.29 g pyridine and 1.66 g acetic anhydride was added into the polyamic acid solution as a chemical conversion agent, the film casting and imidization procedure is the same as Example 1 describes. The obtained polyimide film was used to do a related test.

### Comparative Example 2

A 500 ml three neck round bottom flask fitted with a nitrogen inlet and mechanical stirrer was added to 305.60 g of solvent N, N-dimethylacetamide followed by 32.00 g (0.1 mol) of 2,2′-trifluoromethylbenzidine (TFMB). The mixture was stirred at 50° C. to dissolve the diamines to get a clear solution. Then, 44.40 g (0.1 mol) 4,4′-(hexafluoroisopropylidene)diphthalic anhydride (6FDA) was added slowly to react with diamine. The mixture was then stirred at an ice water bath for 15 hours, to get a polyamic acid solution with a viscosity of 1200 poise.

The polyamic acid solution obtained above was cast and imidized by thermal method and chemical method to make 50 um polyimide film. 1.03 g pyridine and 1.34 g acetic anhydride was added into the polyamic acid solution as a chemical conversion agent, the film casting and imidization procedure is the same as Example 1 describes. The obtained polyimide film was used to do a related test.

### Comparative Example 3

A 500 ml three neck round bottom flask fitted with a nitrogen inlet and mechanical stirrer was added to 245.60 g of solvent N,N-dimethylacetamide followed by 32.00 g (0.1 mol) of 2,2′-trifluoromethylbenzidine (TFMB). The mixture was stirred at 50° C. to dissolve the diamines to get a clear solution. Then, 26.46 g (0.09 mol) 3,3′,4,4′-biphenyl tetracarboxylic dianhydride (BPDA) and 2.94 g (0.01 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 1420 poise.

The polyamic acid solution obtained above was cast and imidized by thermal method and chemical method to make 50 um polyimide film. 1.28 g pyridine and 1.65 g acetic anhydride was added into the polyamic acid solution as a chemical conversion agent, the film casting and imidization procedure is the same as Example 1 describes. The obtained polyimide film was used to do a related test.

### Comparative Example 4

A 500 ml three neck round bottom flask fitted with a nitrogen inlet and mechanical stirrer was added to 299.60 g of solvent N, N-dimethylacetamide followed by 32.00 g (0.1 mol) of 2,2′-trifluoromethylbenzidine (TFMB). The mixture was stirred at 50° C. to dissolve the diamines to get a clear solution. Then, 39.96 g (0.09 mol) 4,4′-(hexafluoroisopropylidene)diphthalic anhydride (6FDA) and 2.94 g (0.01 mol) 2,3,3′,4′-biphenyl tetracarboxylic dianhydride (a-BPDA) were added slowly to react with diamine. The mixture was then stirred at an ice water bath for 15 hours, to get a polyamic acid solution with a viscosity of 1100 poise.

The polyamic acid solution obtained above was cast and imidized by thermal method and chemical method to make 50 um polyimide film. 1.05 g pyridine and 1.36 g acetic anhydride was added into the polyamic acid solution as a chemical conversion agent, the film casting and imidization procedure is the same as Example 1 describes. The obtained polyimide film was used to do a related test.

### Comparative Example 5

A 500 ml three neck round bottom flask fitted with a nitrogen inlet and mechanical stirrer was added to 211.68 g of solvent N, N-dimethylacetamide followed by 19.20 g (0.06 mol) of 2,2′-trifluoromethylbenzidine (TFMB) and 4.32 g (0.04 mol) of 1,3-benzenediamine (m-PDA). The mixture was stirred at 50° C. to dissolve the diamines to get a clear solution. Then, 29.40 g (0.10 mol) 3,3′,4,4′-biphenyl tetracarboxylic dianhydride (BPDA) was added slowly to react with diamine. The mixture was then stirred at an ice water bath for 15 hours, to get a polyamic acid solution with a viscosity of 2130 poise.

The polyamic acid solution obtained above was cast and imidized by thermal method and chemical method to make 50 um polyimide film. 1.49 g pyridine and 1.93 g acetic anhydride was added into the polyamic acid solution as a chemical conversion agent, the film casting and imidization procedure is the same as Example 1 describes. The obtained polyimide film was used to do a related test.

### Comparative Example 6

A 500 ml three neck round bottom flask fitted with a nitrogen inlet and mechanical stirrer was added to 318.72 g of solvent N, N-dimethylacetamide followed by 19.20 g (0.06 mol) of 2,2′-trifluoromethylbenzidine (TFMB) and 4.32 g (0.04 mol) of 1,3-benzenediamine (m-PDA). The mixture was stirred at 50° C. to dissolve the diamines to get a clear solution. Then, 44.40 g (0.10 mol) 4,4′-(hexafluoroisopropylidene)diphthalic anhydride (6FDA) was added slowly to react with diamine. The mixture was then stirred at an ice water bath for 15 hours, to get a polyamic acid solution with a viscosity of 1600 poise.

The polyamic acid solution obtained above was cast and imidized by thermal method and chemical method to make 50 um polyimide film. 0.98 g pyridine and 1.26 g acetic anhydride was added into the polyamic acid solution as a chemical conversion agent, the film casting and imidization procedure is the same as Example 1 describes. The obtained polyimide film was used to do a related test.

### Test Results

The properties test results of examples are listed in Table.1˜2, of comparative examples are listed in Table.3.

In the data below, the examples 1 to 8 suggest that the polyimide film comprising asymmetric dianhydride, and examples 9-16 suggest that polyimide film containing asymmetric dianhydride and meta-substituted diamine together all have low birefringence and high T_{g}. However, the polyimide films obtained in comparative example 1 to 6, which don't comprise non-linear structure, like asymmetric dianhydride and meta-substituted diamine have a larger birefringence than films obtained in example 1 to 16. Consequently, the polyimide obtained in example 1 to 6 with a low birefringence and high T_{g} can be applied in an electro-optic field such as flexible OLED and LCD displays.

TABLE 1
The properties of polyimide film in example 1~8

| | | | Number | | | | | | | |
|---|---|---|---|---|---|---|---|---|---|---|
| | | | Ex. 1 | Ex. 2 | Ex. 3 | Ex. 4 | Ex. 5 | Ex. 6 | Ex. 7 | Ex. 8 |
| Chemical | Dianhydride | s-BPDA | 8 | 6 | 4 | 2 | | | | |
| structure | | 6FDA | | | | | 8 | 6 | 4 | 2 |
| | | a-BPDA | 2 | 4 | 6 | 8 | 2 | 4 | 6 | 8 |
| | Diamine | TFMB | 10 | 10 | 10 | 10 | 10 | 10 | 10 | 10 |
| | | m-PDA | | | | | | | | |
| Thermal | Thickness (μm) | | 50 ± 2 | 50 ± 2 | 50 ± 2 | 50 ± 2 | 50 ± 2 | 50 ± 2 | 50 ± 2 | 50 ± 2 |
| imidization | Transmit- | 400-700 nm | 81.25 | 81.42 | 83.54 | 84.75 | 88.62 | 87.88 | 87.03 | 86.49 |
| method | tance (%) | 550 nm | 88.09 | 88.23 | 88.84 | 88.92 | 89.87 | 89.50 | 88.78 | 88.07 |
| | Δn⊥ | | 0.0043 | 0.0032 | 0.0016 | 0.0007 | 00042 | 0.0027 | 0.0018 | 0.0006 |
| | Rth (nm, @50 μm) | | 215 | 160 | 80 | 35 | 210 | 135 | 90 | 30 |
| | Tg (° C.) | | 312 | 309 | 304 | 301 | 317 | 315 | 311 | 310 |
| | b* | | 4.05 | 3.82 | 3.70 | 2.60 | 2.42 | 2.66 | 3.31 | 3.58 |
| | Yellowness index | | 6.72 | 6.37 | 6.15 | 4.51 | 4.02 | 4.45 | 5.49 | 5.76 |
| | Haze (%) | | 0.02 | 0.00 | 0.04 | 0.03 | 0.02 | 0.00 | 0.06 | 0.05 |
| Chemical | Thickness (μm) | | 50 ± 2 | 50 ± 2 | 50 ± 2 | 50 ± 2 | 50 ± 2 | 50 ± 2 | 50 ± 2 | 50 ± 2 |
| imidization | Transmit- | 400-700 nm | 81.72 | 82.35 | 82.67 | 85.69 | 88.76 | 88.56 | 87.59 | 86.74 |
| method | tance (%) | 550 nm | 88.23 | 88.78 | 89.01 | 89.27 | 90.03 | 89.87 | 89.16 | 88.35 |

| | | | | | | | | |
|---|---|---|---|---|---|---|---|---|
| Δn⊥ | 0.0048 | 0.0039 | 0.0017 | 0.0009 | 0.0049 | 0.0034 | 0.0019 | 0.0008 |
| Rth (nm, @50 μm) | 245 | 195 | 85 | 45 | 245 | 175 | 95 | 40 |
| Tg (° C.) | 316 | 312 | 306 | 304 | 321 | 319 | 313 | 312 |
| b* | 3.82 | 3.41 | 3.49 | 2.51 | 2.13 | 2.31 | 3.07 | 3.36 |
| Yellowness index | 6.26 | 5.64 | 5.83 | 4.22 | 3.50 | 3.87 | 5.08 | 5.57 |
| Haze (%) | 0.45 | 0.32 | 0.16 | 0.17 | 0.43 | 0.23 | 0.25 | 0.27 |

TABLE 2
The properties of polyimide film in example 9~16

| | | | Number | | | | | | | |
|---|---|---|---|---|---|---|---|---|---|---|
| | | | Ex. 9 | Ex. 10 | Ex. 11 | Ex. 12 | Ex. 13 | Ex. 14 | Ex. 15 | Ex. 16 |
| Chemical | Dianhydride | s-BPDA | 8 | 6 | 4 | 2 | | | | |
| structure | | 6FDA | | | | | 8 | 6 | 4 | 2 |
| | | a-BPDA | 2 | 4 | 6 | 8 | 2 | 4 | 6 | 8 |
| | Diamine | TFMB | 8 | 6 | 5 | 5 | 8 | 6 | 5 | 5 |
| | | m-PDA | 2 | 4 | 5 | 5 | 2 | 4 | 5 | 5 |
| Thermal | Thickness (μm) | | 50 ± 2 | 50 ± 2 | 50 ± 2 | 50 ± 2 | 50 ± 2 | 50 ± 2 | 50 ± 2 | 50 ± 2 |
| imidzation | Transmit- | 400-700 nm | 80.76 | 80.62 | 79.43 | 80.01 | 87.11 | 85.26 | 83.12 | 83.43 |
| method | tance (%) | 550 nm | 87.42 | 86.03 | 85.70 | 86.12 | 88.35 | 87.95 | 86.23 | 86.75 |
| | Δn⊥ | | 0.0041 | 0.0015 | 0.0006 | 0.0004 | 0.0033 | 0.0010 | 0.0004 | 0.0004 |
| | Rth (nm, @50 μm) | | 205 | 75 | 30 | 20 | 165 | 50 | 20 | 20 |
| | Tg (° C.) | | 315 | 319 | 317 | 315 | 313 | 320 | 319 | 317 |
| | b* | | 8.6 | 9.56 | 10.32 | 10.11 | 3.62 | 6.00 | 9.26 | 9.43 |
| | Yellowness index | | 13.98 | 15.83 | 17.11 | 16.84 | 5.97 | 9.94 | 15.28 | 15.72 |
| | Haze (%) | | 0.18 | 0.05 | 0.14 | 0.09 | 0.00 | 0.03 | 0.02 | 0.04 |
| Chemical | Thickness (μm) | | 50 ± 2 | 50 ± 2 | 50 ± 2 | 50 ± 2 | 50 ± 2 | 50 ± 2 | 50 ± 2 | 50 ± 2 |
| imidization | Transmit- | 400-700 nm | 81.69 | 80.87 | 80.24 | 80.32 | 87.32 | 85.41 | 83.50 | 83.84 |
| method | tance (%) | 550 nm | 87.47 | 86.35 | 87.12 | 86.57 | 88.92 | 88.04 | 86.92 | 86.98 |

| | | | | | | | | |
|---|---|---|---|---|---|---|---|---|
| Δn⊥ | 0.0048 | 0.0031 | 0.0017 | 0.0008 | 0.0049 | 0.0025 | 0.0016 | 0.0008 |
| Rth (nm, @50 μm) | 245 | 155 | 75 | 40 | 245 | 125 | 80 | 40 |
| Tg (° C.) | 317 | 330 | 323 | 319 | 313 | 322 | 320 | 318 |
| b* | 6.35 | 6.04 | 8.63 | 9.94 | 3.24 | 5.77 | 8.69 | 9.10 |
| Yellowness index | 10.37 | 9.89 | 14.21 | 16.20 | 5.41 | 9.58 | 14.34 | 15.01 |
| Haze (%) | 0.13 | 0.01 | 0.07 | 0.08 | 0.02 | 0.13 | 0.15 | 0.03 |

TABLE 3
The properties of polyimide film in comparative examples 1~6

| | | | Number | | | | | |
|---|---|---|---|---|---|---|---|---|
| | | | Comp. 1 | Comp. 2 | Comp. 3 | Comp. 4 | Comp. 5 | Comp. 6 |
| Chemical | Dianhydride | s-BPDA | 10 | | 9 | | 10 | |
| structure | | 6FDA | | 10 | | 9 | | 10 |
| | | a-BPDA | | | 1 | 1 | | |
| | Diamine | TFMB | 10 | 10 | 10 | 10 | 6 | 6 |
| | | m-PDA | | | | | | |
| | | p-PDA | | | | | 4 | 4 |
| Thermal | Thickness (μm) | | 50 ± 2 | 50 ± 2 | 50 ± 2 | 50 ± 2 | 50 ± 2 | 50 ± 2 |
| imidzation | Transmittance | 400-700 nm | 82.22 | 88.26 | 82.43 | 88.31 | 65.02 | 72.04 |
| method | (%) | 550 nm | 86.99 | 89.44 | 86.97 | 89.66 | 76.62 | 83.13 |
| | Δn⊥ | | 0.0440 | 0.0320 | 0.0230 | 0.0181 | 0.1014 | 0.1121 |
| | Rth (nm, @50 μm) | | 2200 | 1600 | 1150 | 905 | 5205 | 5605 |
| | Tg (° C.) | | 332 | 337 | 327 | 341 | 358 | 353 |
| | b* | | 8.49 | 2.02 | 8.03 | 2.01 | 30.58 | 25.41 |
| | Yellowness index | | 14.57 | 3.30 | 13.87 | 3.27 | 47.56 | 40.39 |
| | Haze (%) | | 5.31 | 0.16 | 4.22 | 0.14 | 10.09 | 7.23 |
| Chemical | Thickness (μm) | | 50 ± 2 | 50 ± 2 | 50 ± 2 | 50 ± 2 | 50 ± 2 | 50 ± 2 |
| imidization | Transmittance | 400-700 nm | 83.36 | 89.01 | 83.67 | 89.03 | 65.31 | 76.32 |
| method | (%) | 550 nm | 87.85 | 89.93 | 88.12 | 89.91 | 76.84 | 84.16 |

| | | | | | | |
|---|---|---|---|---|---|---|
| Δn⊥ | 0.0461 | 0.0410 | 0.0270 | 0.0290 | 0.1087 | 0.1141 |
| Rth (nm, @50 μm) | 2305 | 2050 | 1350 | 1450 | 5435 | 5705 |
| Tg (° C.) | 347 | 345 | 342 | 344 | 363 | 354 |
| b* | 4.30 | 1.71 | 4.13 | 1.80 | 27.64 | 21.79 |
| Yellowness index | 7.12 | 2.70 | 6.42 | 2.92 | 42.12 | 34.50 |
| Haze (%) | 0.71 | 0.26 | 0.57 | 0.09 | 8.34 | 6.12 |

What is claimed is:

1. A polyimide film, comprising:
a condensation polymerization reaction of at least two dianhydrides and at least two diamines;
wherein the molar ratio of the at least two diamines to the at least two dianhydrides is in the range of from 0.95 to 1.1;
wherein the at least two dianhydrides comprise an asymmetric dianhydride and at least one other dianhydride, with the asymmetric dianhydride present at between 20 and 80 mol % of the at least two dianhydrides;
wherein the at least two diamines comprise at least one meta-substituted diamine and at least one other diamine, with the meta-substituted diamine present at no more than 50 mol % of the at least two diamines;
wherein the asymmetric dianhydride is selected from the group consisting of: 2,3,3′,4′-biphenyl dianhydride (a-BPDA), 3,4′-(hexafluorobenzophenone) diphthalic anhydride (a-6FDA), 2,3,3′,4′-benzophenone dianhydride (a-BTDA), 2,2,3′,4′-diphenylsulfonetetracarboxylic dianhydride (a-DSDA) and 2,3,3′,4′-diphenyl ether tetracarboxylic acid dianhydride (a-ODPA);
wherein each of the at the least one other dianhydrides is selected from the group consisting of: 3,3′,4,4′-benzophenonetetracarboxylic dianhydride (BTDA), 3,3′,4,4′-biphenyl tetracarboxylic dianhydride (BPDA), 4,4′-(hexafluoroisopropylidene)diphthalic anhydride (6FDA), 3,3′,4,4′-diphenylsulfonetetracarboxylic dianhydride (DSDA), bicyclo[2,2,2]otc-7-ene-2,3,5,6-tetracarboxylic dianhydride (BTA), bis-(3-phthalyl anhydride) ether (ODPA), 4,4′-(4,4′-isopropylidenediphenoxy)bis(phthalic anhydride) (HBDA), 4-(2,5-Dioxotetrahydrofuran-3-yl)-1,2,3,4-tetrahydronaphthalene-1,2-dicarboxylic anhydride (TDA), 1,2,4,5-cyclohexanetetracarboxylic dianhydride (HPMDA), cyclobutane-1,2,3,4-tetracarboxylic acid dianhydride (CBDA), 1,2,3,4-cyclopentanetetracarboxylic dianhydride (CPDA);
wherein each of the meta-substituted diamines is selected from the group consisting of: 1,3-benzenediamine (m-PDA), 3,3′-diaminodiphenylsulfone (3,3′-DDS), 1,3-cyclohexanediamine (1,3-CHDA), 1,3-cyclohexanebis(methylamine) (CBMA), 3,4′-oxydianiline (3,4′-ODA), 3-(3-aminophenoxy)aniline (3,3-ODA), 3-aminobenzylamine, 3,3′-diaminodiphenylmethane, 2,7-diaminofluorene, 1,3-bis(aminomethyl)benzene (MXDA), 1,3-bis (3-aminophenoxy)benzene (1,3,3-APB), 2,2-Bis(3-amino-4-hydroxyphenyl)hexafluoropropane (DBOH), 2,2-bis(3-aminophenyl)hexafluoropropane (3,3′-6F), 1,4-bis (3-aminophenoxy)benzene (1,4,3-APB), 2,2-bis(3-amino-4-methylphenyl)hexafluoropropane, bis[4-(3-aminophenoxy)-phenyl] sulfone, 3,3′-diaminobenzophenone, 3,4′-diaminodiphenyl ether, 3,3′-trifluoromethylbenzidine (3,3′-TFMB), 5-trifluoromethyl-1,3-benzenediamine, 1,2-bis(3-aminophenoxy) benzene (1,2,3-BAPB); and
wherein each of the at least one other diamines is selected from the group consisting of: 2,2′-trifluoromethylbenzidine (TFMB), 4,4′-[1,4-phenylenebis(oxy)]bis[3-(trifluoromethyl]benzenamine (6FAPB), 2,2′-bis-trifluoromethoxy-biphenyl-4,4′-diamine (BTMBD), 2,2-bis[4-(4-aminophenoxy)phenyl]hexafluoropropane (HFBAPP), 2,2-bis(4-aminophenyl)hexafluoropropane, 9,9-bis(4-amino-3-fluorophenyl)fluorene (FFDA), 1,4-cyclohexylenediamine (1,4-CHDA), 1,4-cyclohexanedimethanamine (1,4-CHDMA), 1,1-bis(4-aminophenyl)-cyclohexane, 4,4′-diaminooctafluorobiphenyl.

2. The polyimide film of claim 1, wherein:
the asymmetric dianhydride is 2,3,3′,4′-biphenyl dianhydride (a-BPDA); and
the at least one other dianhydride is 3,3′,4,4′-biphenyl tetracarboxylic dianhydride (BPDA) and, optionally, 4,4′-(hexafluoroisopropylidene)diphthalic anhydride (6FDA);
wherein 40-80 mol % of the total dianhydride is 3,3′,4,4′-biphenyl tetracarboxylic dianhydride (BPDA).

3. The polyimide film of claim 2, wherein:
the at least two diamines comprise 1,3-benzenediamine (m-PDA) and 2,2′-trifluoromethylbenzidine (TFMB);
wherein 20 to 50 mol % of the total diamine is 1,3-benzenediamine (m-PDA).

4. The polyimide film of claim 1, wherein:
the at least two diamines comprise 1,3-benzenediamine (m-PDA) and 2,2′-trifluoromethylbenzidine (TFMB);
wherein 20 to 50 mol % of the total diamine is 1,3-benzenediamine (m-PDA).

5. The polyimide film of claim 2, wherein the diamine comprises 2,2′-trifluoromethylbenzidine (TFMB).

6. The polyimide film of claim 1, wherein the diamine comprises 2,2′-trifluoromethylbenzidine (TFMB).

7. The polyimide film of claim 1, wherein the molar ratio of dianhydride and diamine is from 0.98˜1.05.

8. The polyimide film of claim 1, wherein:
the film is characterized by all three of the following features:
a transmittance at 550 nm of at least 85%;
a birefringence of 0.005 or less; and
a glass transition temperature of at least 300° C.

9. A method for producing the polyimide film of claim 1, comprising the following steps:
preparing a polyamic acid solution by a condensation polymerization reaction of at least two dianhydrides and at least two diamines in at least one solvent selected from the group consisting of N-methyl-2-pyrrolidone (NMP), dimethylacetamide (DMAc), dimethylformamide (DMF), dimethylsulfoxide (DMSO), m-cresol, chloroform, terahydrofuran (THF), γ-butyrolactone, 3-methoxy-N,N-dimethylpropanamide;
completing the imidization of the polyamic acid to obtain a polyamide film, using at least one of a thermal imidization and a chemical imidization method;
removing the solvent from the polyimide film and fixing the polyimide film to a frame using steel pins; and
curing the polyimide film at 80° C. to 400° C. for 30 to 120 minutes in a high temperature oven.

10. The method of claim 9, wherein:
a catalyst, selected from the group consisting of: pyridine, methyl pyridines, quinoline, isoquinoline, 1-methyl imidazole, 1, 2-dimethyl imidazole and 2-methyl imidazole, is added to the polyamic acid solution;
a dehydrating agent, selected from the group consisting of: acetic anhydride, propionic anhydride, butyric anhydride, benzoic anhydride, is added to the polyamic acid solution;
the polyamic acid solution is cast on a glass plate;
the imidization is completed in a high temperature oven.

11. The method of claim 9, wherein the polyimide film is heated at 200 to 400° C. for 2 to 60 mins after the curing process.

12. A substrate or cover window of a flexible organic light emitting diode (OLED) display or a flexible liquid crystal display (LCD), comprising a polyimide film of claim 1.
